(19) United States
(12) Patent Application Publication
(10) Pub. No.: US 2008/0050917 A1
(43) Pub. Date: Feb. 28, 2008

(54) METHOD OF MANUFACTURING SEMICONDUCTOR DEVICE

(76) Inventor: Ji-Ho Hong, Gyeonggi-do (KR)

Correspondence Address: SHERR & NOURSE, PLLC, 620 HERNDON PARKWAY, SUITE 200, HERNDON, VA, 20170, US

(21) Appl. No.: 11/841,028

(22) Filed: Aug. 20, 2007

(30) Foreign Application Priority Data
Aug. 22, 2006 (KR) 10-2006-0079327

(51) Int. Cl. H01L 21/302

(52) U.S. Cl. 438/692; 257/E21.214

(57) ABSTRACT

A method of manufacturing a semiconductor device improves the cleaning efficiency by increasing a cleaning time and temperature, including a copper Chemical Mechanical Planarization process for a semiconductor wafer with a copper line. The method includes a main Cu CMP process to chemically and mechanically polish a surface of the semiconductor wafer. A touch-up CMP process chemically and mechanically polishes a barrier metal exposed on the surface of semiconductor wafer and a lower insulation film positioned below the barrier metal. A CMP cleaning process to remove defects occurring in the main Cu CMP process and the touch-up CMP process by supplying a chemical cleaner to the surface of semiconductor wafer.

The present application claims priority under 35 U.S.C. 119 to Korean Patent Application No. 10-2006-0079327, filed on 22 Aug. 2006, which is hereby incorporated by reference in its entirety.

### BACKGROUND

With the trend of higher integration in semiconductor devices, a need has arisen for a multi-layer metal line structure and a smaller spacing between metal lines. In attempting to meet this need, difficulties increase with parasitic capacitance (C) and parasitic resistance (R) elements between horizontally and vertically adjacent metal line layers.

In a metal line system, parasitic capacitance (C) and parasitic resistance (R) elements induce a parasitic RC delay, reducing signaling speed in the device. Parasitic RC also increases power consumption. Signal leakage is also increased. For more highly integrated semiconductor devices, it may be advantageous to develop a multi-layer metal line technology with high speed operation and small parasitic RC characteristics. To form a line having relatively small parasitic RC characteristics, a line may be formed of a metal having a low specific resistance. The line may be provided with an insulation film having a low dielectric constant. For example, the line may be formed of copper (Cu), aluminum (Al), silver (Ag), gold (Au), or alloys thereof. Active research is directed towards using copper (Cu).

Copper (Cu) has low specific resistance, reasonable price and small load on fabrication. Unlike aluminum (Al), copper (Cu) has a relatively high tolerance to electro-migration. These and other advantages have increased interest in copper. However, since copper has a high chemical affinity, copper is easily diffused into a silicon substrate or a silicon oxide film. To prevent higher rates of diffusion of copper and/or to improve the adherence, a barrier layer using titanium (Ti) or tantalum (Ta) based metal alloy may be formed between the silicon oxide film and a contact.

It may also be difficult to form a line pattern of copper by etching. A damascene process may be used to form a copper line pattern. Damascene processes may be classified into single damascene processes and dual damascene processes.

The copper dual damascene process has generated much interest. However, the dual damascene process has various difficulties. A planarization process to remove the undesired portion of copper film deposited, that is, copper chemical mechanical planarization (Cu CMP) process, may cause various defects. The Cu CMP process corresponds to a polishing process for the metal layer, which has large effects on the yield of the dual damascene process.

A related art Cu CMP process will be briefly explained as follows. Relatively large amounts of copper may be polished by chemical and mechanical planarization (CMP). A barrier metal and an insulation film may be polished in a chemical and mechanical planarization, that is, touch-up (TUP) CMP.

A metal line for a semiconductor wafer formed by the aforementioned method may have defects such as slurry particles and metal residue on the metal line polished by Cu CMP and TUP CMP process. These defects are related to the Cu CMP process. In particular, these defects may occur as a barrier metal of TaN or Ta and some insulation film are polished by the TUP CMP process after removing the large amounts of copper by the Cu CMP process.

Since the exact causes of CMP particle defects have eluded precise explanation, there have been no effective methods to cope with these defects. Also, defect residues may cause short circuits, degrading yield and reliability.

### SUMMARY

Embodiments relate to a method of manufacturing a semiconductor device, and more particularly, to a method of manufacturing a semiconductor device with fewer defects caused by a copper chemical mechanical planarization (Cu CMP) process on a semiconductor wafer having copper lines formed by a damascene process.

Embodiments relate to a method of manufacturing a semiconductor device which may improve the reliability of copper line layers by removing contaminants or defects related to a Cu CMP process.

Embodiments relate to a method of manufacturing a semiconductor device which may improve the yield of line processes with an improved CMP process by removing CMP residues effectively. The method may decrease fabrication costs.

Embodiments relate to a method of manufacturing a semiconductor device, including a Cu CMP process for a semiconductor wafer having a copper line. The method may include a main Cu CMP process to chemically and mechanically polish a surface of the semiconductor wafer using a slurry including a polisher. A TUP CMP process may be used to chemically and mechanically polish a barrier metal exposed on the surface of semiconductor wafer and a lower insulation film positioned below the barrier metal after the main Cu CMP process is carried out. A CMP cleaning process may remove defects occurring in the main Cu CMP process and the TUP CMP process by supplying a chemical cleaner to the surface of semiconductor wafer.

### DRAWINGS

Example FIG. 1 is a flowchart to illustrate a method of manufacturing a semiconductor device according to embodiments.

Example FIGS. 2A and 2B are exemplary cross section views to illustrate a method of manufacturing a semiconductor device shown in example FIG. 1.

FIGS. 3A and 3B are cross sectional views to illustrate defects which may occur in a fabrication process of semiconductor device according to the related art.

Example FIGS. 4A and 4B are graphs to show particle occurrence in relation with a cleaning time and a temperature of chemical cleaner.

### DESCRIPTION

FIG. 1 is a flowchart to illustrate a method of manufacturing a semiconductor device according to embodiments. FIGS. 2A and 2B are exemplary cross sectional views of a semiconductor device to illustrate a method of manufacturing a semiconductor device shown in FIG. 1. The devices may include a substrate 48, a lower line 46, a barrier metal 42 and 42′, a copper film 40, and an upper line 40′. In this case, the lower line 46 and the upper line 40′ may be formed of copper metal.

An exemplary cross sectional view of the semiconductor device is shown in FIG. 2. However, it is not limited to this cross section view of FIG. 2. Embodiments relate to any method of manufacturing a semiconductor device having a copper line.

In a semiconductor wafer having a copper line formed through an electro chemical plating (ECP) process of a damascene process (S10), a main Cu CMP process using slurry including a polisher may be applied to undesired portions of a copper film 40. To increase thermal stability after a Cu ECP process, a Cu CMP process may be performed after an annealing process. As large amounts of copper 40 are polished, a barrier metal 42 having a predetermined thickness may be removed. Copper with a large etching selection ratio may be provided.

In the main Cu CMP process, an etching time for copper on the surface of a semiconductor wafer may be set by using an End Point Detector (EPD). That is, the Cu CMP process may be performed until the barrier metal 42 is exposed by polishing. The EPD process may be positioned at the end of each process in the semiconductor fabrication. As the etching time for the wafer surface is set, the processing quality of semiconductor wafer may be determined.

A touch-up CMP (TUP CMP) process may be applied to remove the barrier metal 42 and predetermined upper portions of insulation film 44 positioned below the barrier metal 42, to prevent a metal bridge (S20) or short circuit. The barrier metal 42 may be polished to a thickness below 1000 Å, and the predetermined upper portions of the insulation film 44 positioned below the barrier metal 42 may be polished to a thickness of about several hundreds of angstroms. For convenience, the selection ratio of the barrier metal 42 and the predetermined upper portions of the insulation film 44 may be close to unity. In the main Cu CMP process and the TUP CMP process, various defects may occur.

After performing the main Cu CMP process and the TUP CMP process, a CMP cleaning process using a chemical cleaner may be applied to decrease defects such as copper residue and slurry particles (S30). This cleaning process may be necessary after the CMP process. The chemical cleaner may be used to remove the defects occurring on the surface of the polished semiconductor wafer. The chemical cleaner may be a weak acid cleaner which may include deionized water (DI water) and citric acid, for example.

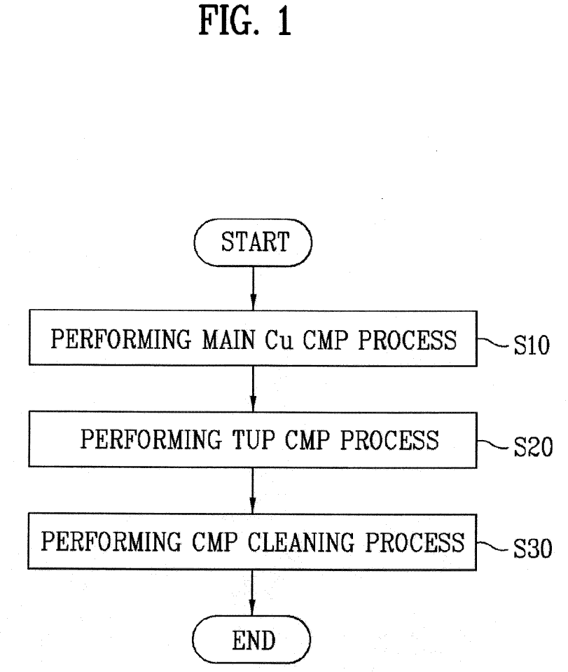

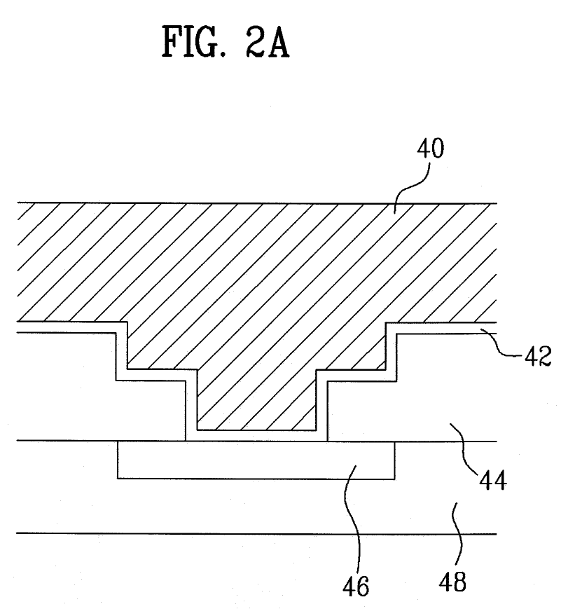

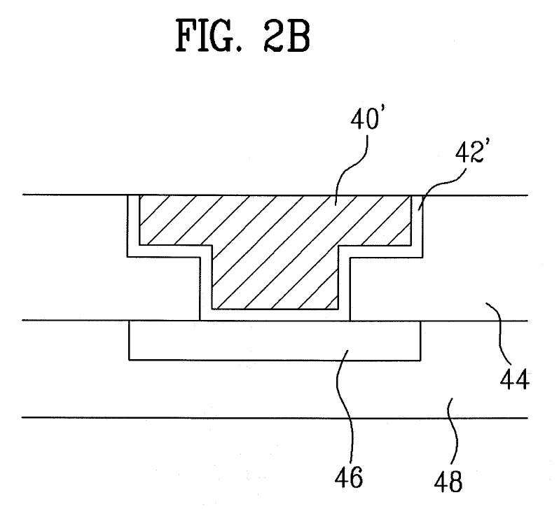

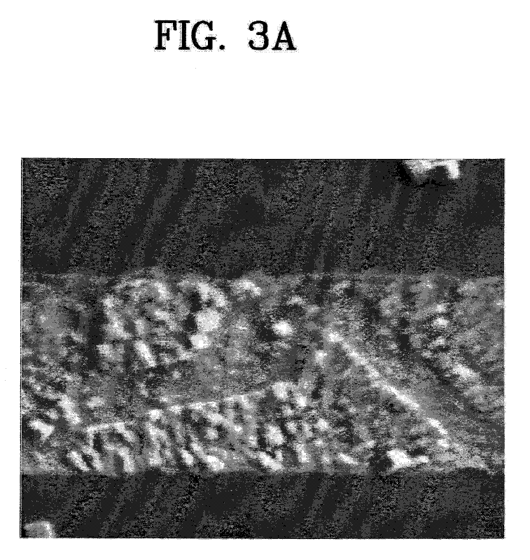

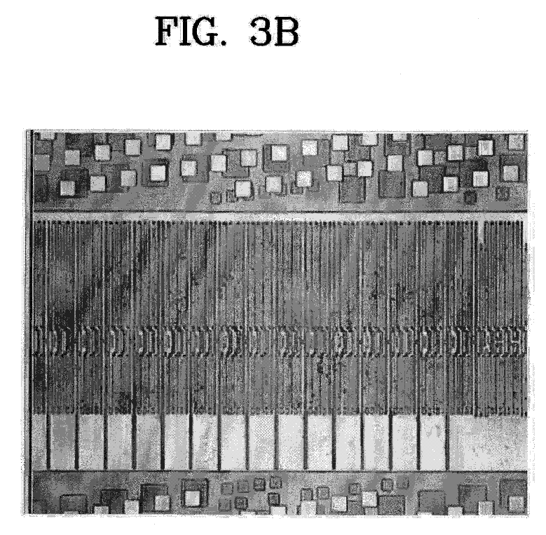

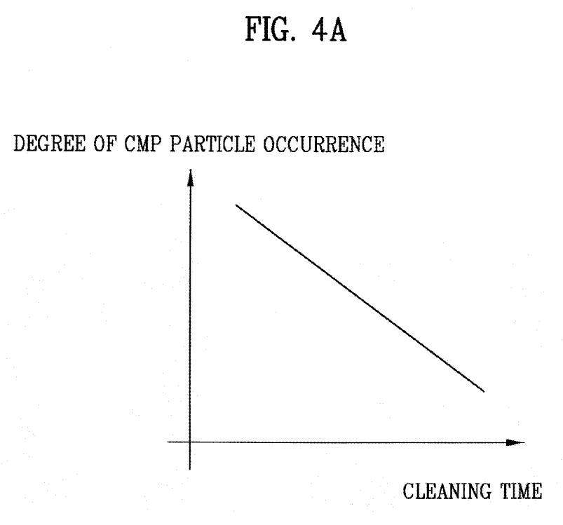

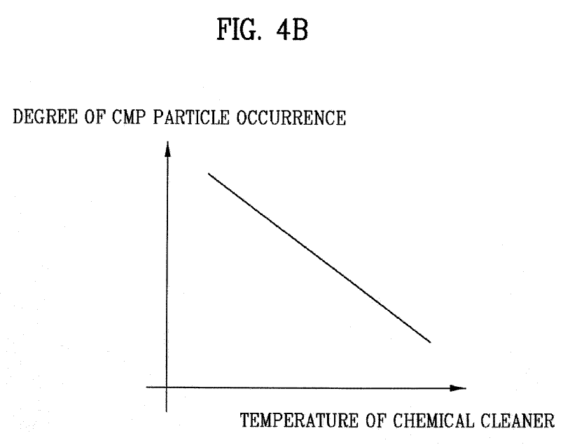

However, as shown in FIG. 3A, when using a chemical cleaner including citric acid, boil-shaped defects may occur in the copper (Cu) on the surface of the wafer. For reference, FIG. 3B illustrates an optical image based on FIG. 3A.

These defects correspond to a residue which may not be completely removed by the CMP cleaning process, and is left on the wafer surface. Also, the temperature of the DI water influences the solubility of dissolved citric acid. Citric acid may assume powdered and lump forms, or columnar crystal forms. Accordingly, it may be assumed from the shape of CMP particle shown in FIG. 3A, that the boil-shaped CMP particle may be closely related to the citric acid used in the TUP CMP process.

Using these assumptions, two procedures may be carried out in a CMP cleaning process according to embodiments. In the first procedure, the cleaning process may be performed under conditions where the chemical cleaner may be supplied in an inflow speed of about 500 ml/minute to about 1000 ml/minute from about 120 seconds to about 240 seconds, and at a temperature of about 15° C. to about 80° C. The chemical cleaner may include materials such as acid-based DHF (diluted HF), alkali-based NH₃, a water solution of ammonia, or citric acid. Any of these materials may be dissolved in DI water. The chemical cleaner has DI water as the main component, and has at least one of DHF, NH₃, or citric acid at a concentration of 0.5% to about 1.0% by weight. The chemical cleaner may have a PH between about 5 to about 6.5.

In this procedure, when performing the CMP cleaning process using the chemical cleaner including citric acid, the occurrence of CMP particle defects on the wafer can be checked. The cleaning time period and the temperature of the chemical cleaner may be gradually increased to find the optimum conditions for a particular process.

As shown in the graphs of FIGS. 4A and 4B, the defects generated in the CMP process such as CMP particles may be gradually removed as the length of time the chemical cleaner is supplied is sufficiently increased and as the temperature of chemical cleaner is increased in the CMP cleaning process.

In the second procedure, a wet cleaning process using a cleaner including an organic solute of NE₁₄, which is effective in removing organic materials, may be carried out after the first procedure using the chemical cleaner, to remove the CMP particles remaining on the semiconductor wafer.

By checking the results of this procedure, it may be known that the remaining CMP particles are gradually decreased as the cleaning time using the chemical cleaner is sufficiently increased and the temperature of chemical cleaner is increased in the CMP cleaning process. The wet cleaning process using the cleaner including the organic solute of NE₁₄, decreases the number of remaining CMP particles more remarkably.

In embodiments, the cause of the CMP particle occurrence due to the CMP cleaning process may be analyzed. The fabrication conditions including the temperature and length of time a cleaner used in the CMP cleaning process may be improved. A semiconductor device including a copper line layer may be manufactured with fewer defects generated by a CMP cleaning process.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
a main copper chemical mechanical planarization process to chemically and mechanically polish a surface of a semiconductor wafer;
a touch-up chemical mechanical planarization process to chemically and mechanically polish a barrier metal; and
a chemical mechanical planarization cleaning process to remove defects occurring in the main copper chemical mechanical planarization process and the touch-up chemical mechanical planarization process.

2. The method of claim 1, wherein said chemical mechanical planarization cleaning process removes defects by supplying a chemical cleaner to the surface of semiconductor wafer.

3. The method of claim 2, wherein the chemical cleaner is formed by dissolving diluted hydrogen fluoride in deionized water.

4. The method of claim 3, wherein the chemical cleaner comprises deionized water as a main component, and diluted hydrogen fluoride at a concentration of 0.5% to 1.0% by weight.

5. The method of claim 2, wherein the chemical cleaner is formed by dissolving ammonia in deionized water.

6. The method of claim 5, wherein the chemical cleaner comprises deionized water as a main component, and ammonia at a concentration of 0.5% to 1.0% by weight.

7. The method of claim 2, wherein the chemical cleaner is formed by dissolving citric acid in deionized water.

8. The method of claim 7, wherein the chemical cleaner comprises deionized water as a main component, and citric acid at a concentration of 0.5% to 1.0% by weight.

9. The method of claim 2, wherein the pH of the chemical cleaner is about 5 to 6.5.

10. The method of claim 2, wherein the chemical cleaner is formed by dissolving one of diluted hydrogen fluoride, ammonia and citric acid in deionized water and wherein the chemical mechanical planarization cleaning process includes an additional cleaning process using an organic cleaner comprising NE₁₄.

11. The method of claim 2, wherein the defects are removed by controlling the temperature of the chemical cleaner and the flow rate of the chemical cleaner supply.

12. The method of claim 2, wherein the chemical cleaner is supplied at a flow rate of 500 ml/minute to 1000 ml/minute.

13. The method of claim 2, wherein the chemical cleaner is supplied for between about 120 seconds to 240 seconds.

14. The method of claim 2, wherein the chemical cleaner is supplied at a temperature of about 15° C. to 80° C.

15. The method of claim 1, wherein said copper chemical mechanical planarization process is used to planarize a semiconductor wafer including a copper line.

16. The method of claim 1, wherein said main copper chemical mechanical planarization process uses a slurry.

17. The method of claim 16, wherein said slurry comprises a polisher.

18. The method of claim 1, wherein said barrier metal is exposed on the surface of semiconductor wafer.

19. The method of claim 1, wherein said touch-up chemical mechanical planarization process planarizes a lower insulation film positioned below said barrier metal.

20. The method of claim 1, wherein said touch-up chemical mechanical planarization process occurs after the main copper chemical mechanical planarization process is carried out.
